(19) United States
(12) Patent Application Publication
(10) Pub. No.: US 2007/0042584 A1
(43) Pub. Date: Feb. 22, 2007

(54) METHOD OF FORMING A SILICIDE

(76) Inventors: Jen-Hong Huang, Tao-Yuan City (TW); Nien-Chung Li, Hsin-Chu City (TW); Yi-Chung Sheng, Tai-Chung City (TW); Chun-Chia Chen, Tai-Chung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/161,756

(22) Filed: Aug. 16, 2005

(51) Int. Cl. H01L 21/44

(52) U.S. Cl. 438/592; 438/595; 438/682

(57) ABSTRACT

At least one gate electrode is formed on a substrate. A first dielectric layer and a second dielectric layer are formed on the gate electrode, respectively. A portion of the second dielectric layer is removed to form a spacer on either side of the gate electrode. A portion of the first dielectric layer is removed to form a notch between the gate electrode and the spacer, the notch having an aspect ratio greater than 1. A self-aligned silicide process is performed to form a silicide on exposed surfaces of the gate electrode and the first dielectric layer underneath the notch.

### BACKGROUND OF INVENTION

1. Field of the Invention

The present invention relates to a method of forming a silicide, and more particularly, to a method of forming a silicide to increase a gate metal contact area.

2. Description of the Prior Art

Metal-oxide-semiconductor (MOS) transistors are important components of semiconductor circuits, and the electrical performance of a gate electrode in the MOS transistor is an important issue that effects the quality of the MOS transistor. The prior art gate electrode typically includes a doped polysilicon layer or a doped amorphous silicon layer used as the main conductive layer, and a silicide layer stacked on the conductive layer. The silicide layer provides a good ohmic contact to the devices of the MOS transistor, thus reducing sheet resistance and enhancing the operational speed of the MOS transistor.

Referring to FIGS. 1-7, FIGS. 1-7 are schematic diagrams of a method of forming a silicide according to the disclosure of U.S. Pat. No. 5,851,890. As shown in FIG. 1, the prior art provides a substrate 2, such as a semiconductor substrate, and the substrate 2 includes a gate insulating layer 4, a polysilicon gate electrode 6 positioned on the gate insulating layer 4, and a plurality of field oxide layers 8 positioned on the substrate 2 at either side of the gate electrode 6. Lightly doped drain (LDD) regions 10 and 12 are formed between the gate electrode 6 and the field oxide layers 8, and an oxide layer 14 is formed on the substrate 2. The oxide layer 14 has a thickness ranging from about 100 Å to 500 Å, and the function of the oxide layer 14 is to provide a buffer layer between the substrate 2 and a spacer subsequently formed on either sidewall of the gate electrode 6. In addition, the oxide layer 14 also serves as an etch stop when defining the pattern of the spacer, so as to prevent the surface of the substrate 2 from being damaged during the etching process.

As shown in FIG. 2 and FIG. 3, spacers 16 and 18, such as silicon nitride spacers, are then formed on the oxide layer 14 at either side of the gate electrode 6, and source/drain regions 20, 22 are formed between the spacers 16, 18 and the field oxide layers 8. As shown in FIG. 4, an etching process, such as a premetallization oxide wet etch, is subsequently performed to remove portions of the oxide layer 14, leaving portions of the oxide layers 14a, 14b between the gate electrode 6 and the spacers 16, 18. During the etching process, notches 24 and 26 are formed underneath the spacer 16 and 18, respectively, to increase a metal contact area on the source/drain regions 20 and 22. In addition, notches 28 and 30 are formed at either side of the gate electrode 6 during the etching process, so as to increase a metal contact area on the gate electrode 6. It is noticeable that the disclosure of U.S. Pat. No. 5,851,890 specifically limits an aspect ratio (i.e., the depth divided by the width) of the notches 24, 26, 28, 30 to being unity or less, so as to ensure the silicide subsequently formed may fill the notches.

As shown in FIG. 5, a metal layer 32 is deposited over the entire surface of the substrate 2 to react with the exposed silicon surfaces to produce silicide. A thickness of the metal layer 32 ranges between 100 Å and 750 Å. Subsequently, as shown in FIG. 6, the structure is heated to a temperature ranging from about 400° C. to about 700° C. for a period of time ranging from about 10 seconds to about 3 minutes, to cause the portions of the metal layer 32 positioned on the source/drain regions 20 and 22 to react with silicon to form suicides 42 and 44 as source/drain metal contacts, and cause the portions of the metal layer 32 positioned on the gate electrode 6 to react with silicon to form a silicide 46 as a gate metal contact. The unreacted portions 34, 36, 38, and 40 of the metal layer are left over the field oxide layers 8 and the silicon nitride spacers 16 and 18.

As shown in FIG. 7, the unreacted portions 34, 36, 38, and 40 are then removed, leaving the silicide 46 on the top of the gate electrode 6 and within the notches 28 and 30, so as to provide the gate metal contact with a uniform thickness.

The prior art method limits the aspect ratio of the notches 28 and 30 to equal to 1 or less than 1, so as to ensure that the silicide 46 has the uniform thickness and the silicide 46 fills the notch 28 between the gate electrode 6 and the spacer 16 and the notch 30 between the gate electrode 6 and the spacer 18. As the dimension of the semiconductor devices shrinks, the width and the top surface area of the gate electrode 6 are reduced. When the top surface area of the gate electrode is reduced, the sheet resistance of the gate electrode is increased. Therefore, it is important to effectively increase the contact area between the silicide and the gate electrode to prevent the problems such as RC delay and low operation frequency of the semiconductor devices.

### SUMMARY OF INVENTION

It is an object of the present invention to provide a method of forming a suicide to increase the area of a gate metal contact.

According to one embodiment of the present invention, at least one gate electrode is formed on a substrate. A first dielectric layer and a second dielectric layer are formed on the gate electrode, respectively. A portion of the second dielectric layer is removed to form a spacer on either side of the gate electrode. A portion of the first dielectric layer is removed to form a notch between the gate electrode and the spacer, the notch having an aspect ratio greater than 1. A self-aligned silicide process is performed to form a silicide on exposed surfaces of the gate electrode and the first dielectric layer underneath the notch.

The present invention limits the aspect ratio of the notch between the gate electrode and the spacer to be greater than 1, so that the area of the exposed sidewall surfaces increases as the depth of the notch increases. Therefore, the present invention provides an advantage of increasing the contact area between the silicide and the gate electrode. In addition, when the depth of the notch increases, the silicide extends from the top and the sidewall of the gate electrode to the surface of the first dielectric layer, providing a hat-shaped cover on the gate electrode and the first dielectric layer. As a result, the advantages of increasing the area of the gate metal contact and reducing the sheet resistance of the gate electrode can be achieved.

These and other objects of the claimed invention will be apparent to those of ordinary skill in the art with reference to the following detailed description of the preferred embodiments illustrated in the various drawings.

### BRIEF DESCRIPTION OF DRAWINGS

FIGS. 1-7 are schematic diagrams of a method of forming a suicide according to the prior art;

FIGS. 8-13 are schematic diagrams of a method of forming a suicide according to a first embodiment of the present invention; and

FIGS. 14-18 are schematic diagrams of a method of forming a suicide according to a second embodiment of the present invention.

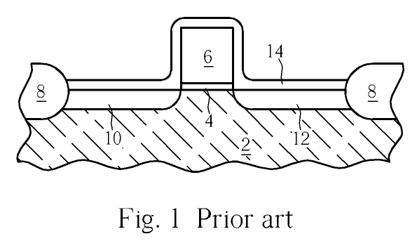

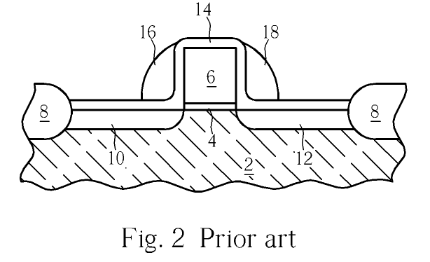

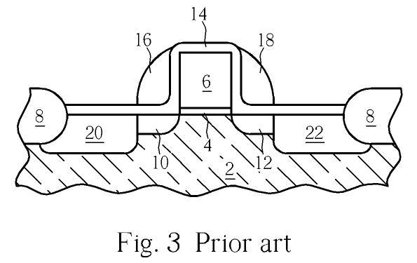

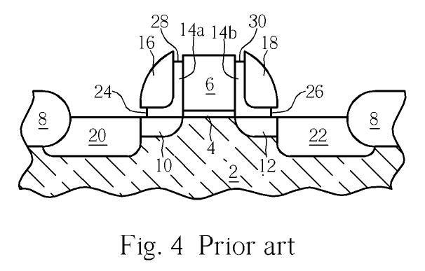

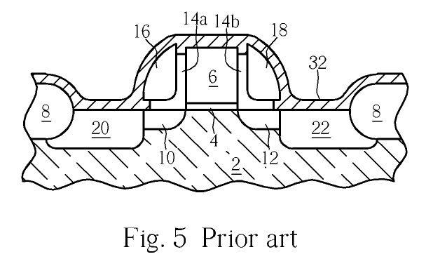

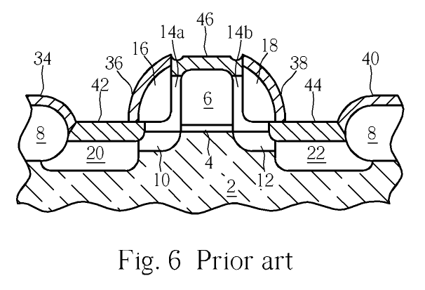

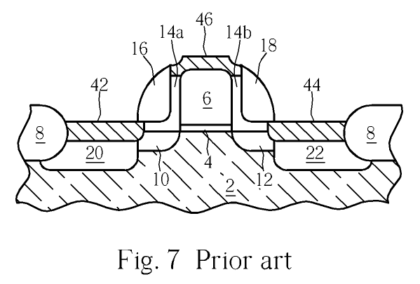

### DETAILED DESCRIPTION

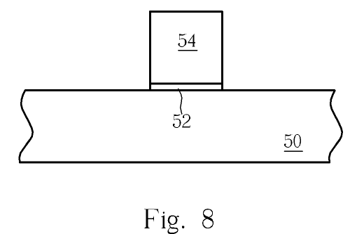

Referring to FIGS. 8-13, FIGS. 8-13 are schematic diagrams of a method of forming a suicide according to the present invention. As shown in FIG. 8, a substrate 50, such as a semiconductor substrate, is provided, a gate insulating layer 52, e.g. a silicon oxide layer, is formed on the substrate 50, and at least one gate electrode 54 is formed on the gate insulating layer 52. The gate electrode 54 includes silicon, such as a polysilicon layer, and the gate electrode 54 may include other material layers.

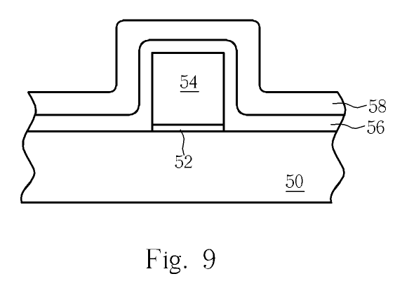

As shown in FIG. 9, a dielectric layer 56 and a dielectric layer 58 are respectively formed on the substrate 50. The dielectric layer 56 can be a liner oxide layer, such as a silicon dioxide layer, a silicon oxy-nitride layer, or a tetra-ethyl-ortho-silicate (TEOS) layer. The dielectric layer 56 is used to provide a buffer layer between the substrate 50 and a spacer subsequently formed on either side of the gate electrode 54. In addition, the dielectric layer 56 is used as an etch stop layer while defining the pattern of the spacer, preventing the substrate 50 from being damaged during the etching process. The dielectric layer 56 can also be a multi-layer dielectric layer, such as an oxide-nitride (ON) dielectric layer, an oxide-nitride-oxide (ONO) dielectric layer, an oxide-nitride-oxide-nitride (ONON) dielectric layer, and so on. A thickness of the dielectric layer 56 is suggested being less than 400 Å, and a preferred thickness of the dielectric layer 56 is about 200 Å. The dielectric layer 58 can be a silicon nitride layer or other suitable materials used to define the spacer on the either side of the gate electrode 54.

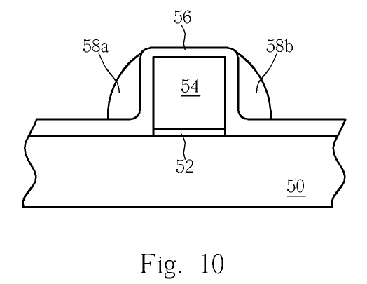

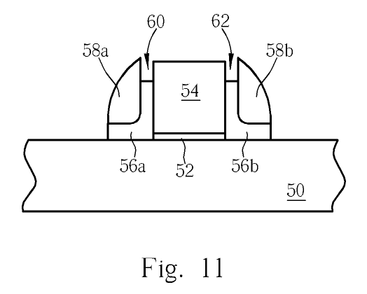

As shown in FIG. 10, an etching process is performed to remove portions of the dielectric layer 58, so as to form a spacer 58a and a spacer 58b on the two sidewalls of the gate electrode 54 and expose the surface of the dielectric layer 56 as well. After the formation of the spacers 58a and 58b, as shown in FIG. 11, another etching process, such as a premetallization oxide wet etch, is performed to remove portions of the dielectric layer 56. As a result, the residual dielectric portions 56a and 56b are left between the gate electrode 54 and the spacers 58a and 58b, and notches 60 and 62 are formed at the two sides of the gate electrode 54 to expose the upper portions of the sidewalls of the gate electrode 54 for increasing the metal contact area on the gate electrode 54. In other embodiments of the present invention, the two etching processes for removing the portions of the dielectric layer 58 and the dielectric layer 56 can be combined in an etching process. The etching process adjusts an etching selectivity ratio to simultaneously complete the formation of the spacers 58a, 58b, and the notches 60, 62.

It is noticeable that, in a better embodiment of the present invention, an aspect ratio of the notches 60 and 62 (i.e., the depth of the notches 60, 62 divided by the width of the notches 60, 62) should be greater than 1, the width of the notches 60, 62 is less than 400 Å, and the depth of the notches 60, 62 is about 10% to 50% of the height of the gate electrode 54. Under this condition, a suicide subsequently formed within the notches 60, 62 can simultaneously cover the upper sidewalls of the gate electrode 54 and the surfaces of the dielectric portions 56a, 56b.

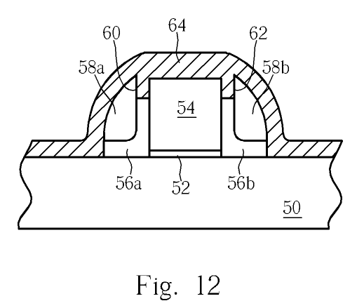

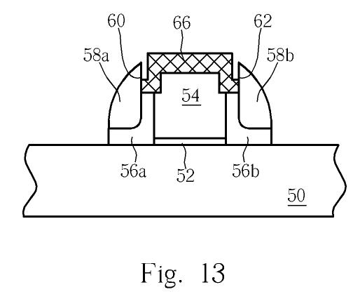

As shown in FIG. 12 and FIG. 13, a self-aligned silicide process is performed to form a silicide 66 into a hat shape on the top and the sidewalls of the gate electrode 54 and on the surfaces of the dielectric portions 56a and 56b. In a better embodiment of the present invention, the silicide 66 does not fill the notches 60 and 62, and the self-aligned silicide process includes the following steps of: forming a metal layer 64 on the substrate 50, the metal layer 64 being formed of the metal Ni/Co/Pt/Pd/Mo or an alloy comprising any of the metal Ni/Co/Pt/Pd/Mo, and the metal layer 64 contacting the exposed top surface and sidewalls of the gate electrode 54 to react with silicon; performing a first rapid thermal treatment to react the atoms in the metal layer 64 with the contacting polysilicon on the gate electrode 54 so as to produce the silicide 66; performing a wet etching process to remove the unreacted portions of the metal layer 64; and performing a second rapid thermal treatment to reduce resistance of the silicide 66 and complete the formation of the silicide 66.

During the formation process of the silicide 66, the silicon atoms in the polysilicon gate electrode 54 may diffuse to the surfaces of the dielectric portions 56a and 56b. The metal layer 64 may react with the silicon atoms on the dielectric portions 56a and 56b to form the brim of the hat-shaped silicide 66, so as to help to increase the gate metal contact area and reduce the resistance of the gate electrode. In addition, the present invention forms the notches 60 and 62 more deeply, so that the metal deposited at the bottom of the notches 60 and 62 may not be removed easily. As a result, it is also helpful to form the brim of the hat-shaped silicide 66.

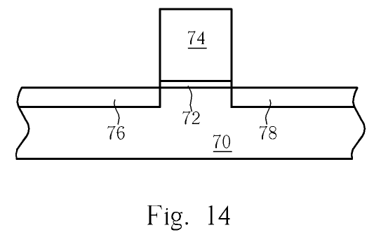

Referring to FIGS. 14-18, FIGS. 14-18 are schematic diagrams of a method of forming a silicide according to another embodiment of the present invention. As shown in FIG. 14, a substrate 70, such as a semiconductor substrate, is provided, a gate insulating layer 72, e.g. a silicon oxide layer, is formed on the substrate 70, at least one gate electrode 74 is formed on the gate insulating layer 72, and a doping process is used to form LDD regions 76 and 78 at the two sides of the gate electrode 74. The gate electrode 74 includes silicon, such as a polysilicon layer, and the gate electrode 74 may include other material layers.

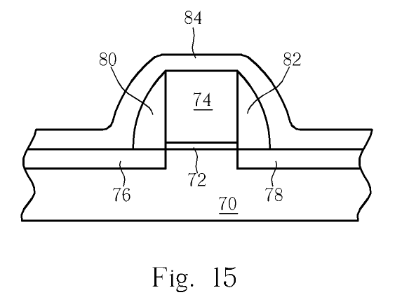

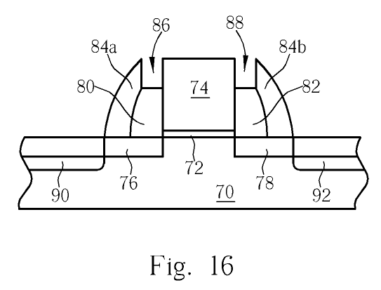

As shown in FIG. 15, spacers 80 and 82 are formed on the two sidewalls of the gate electrode 74. The spacers 80 and 82 can be a single-layer structure, and formed of silicon oxide. However, the spacers 80 and 82 can also be a multi-layer structure, such as an oxide-nitride (ON) dielectric layer, an oxide-nitride-oxide (ONO) dielectric layer, an oxide-nitride-oxide-nitride (ONON) dielectric layer, and so on. The spacers 80 and 82 can be replaced by a liner oxide layer. Following that, a dielectric layer 84, such as a silicon nitride layer, is formed on the substrate 70. As shown in FIG. 16, an etching process is performed to remove portions of the dielectric layer 84, so as to define the patterns of spacers 84a and 84b at the two sides of the gate electrode 74. Subsequently, portions of the spacers 80 and 82 is removed to form notches 86 and 88 between the gate electrode 74 and the spacers 84a and 84b. It is worth noting that the notches 86 and 88 can also be formed simultaneously during the etching process. Namely, during the etching process of the dielectric layer 84, an etching selectivity ratio can be adjusted to simultaneously remove portions of the spacers 80 and 82, thus forming notches 86 and 88 between the gate electrode 74 and the spacers 84a and 84b, and exposing the surfaces of the spacers 80, 82 and the top and the upper sidewalls of the gate electrode 74. Subsequently, a doping process is performed to form source/drain regions 90 and 92 at the two sides of the gate electrode 74.

In other embodiments of the present invention, the step of removing the portions of the spacers 80 and 82 to form the notches 86 and 88 can be separately executed after the formation of the spacers 84a and 84b. It is noticeable that, in a better embodiment of the present invention, an aspect ratio of the notches 86 and 88 (i.e., the depth of the notches 86, 88 divided by the width of the notches 86, 88) should be greater than 1, the width of the notches 86, 88 is less than 400 Å, and the depth of the notches 86, 88 is about 10% to 50% of the height of the gate electrode 74. Under this condition, a silicide subsequently formed within the notches 86, 88 can simultaneously cover the upper sidewalls of the gate electrode 74 and the surfaces of the spacers 80, 82.

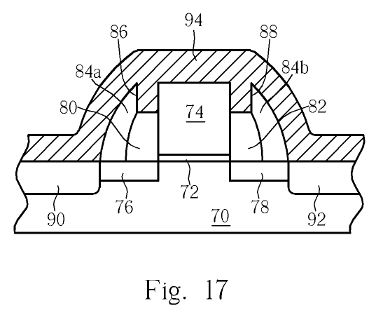

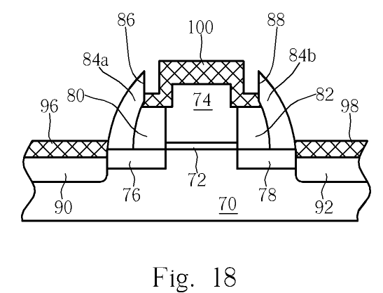

As shown in FIG. 17 and FIG. 18, a self-aligned silicide process is performed to form a silicide 96 on the source/drain region 90, a silicide 98 on the source/drain region 92, and a silicide 100 into a hat shape on the top, the upper sidewalls of the gate electrode 74 and on the spacers 80 and 82. The silicide 96 and the silicide 98 are used as a source/drain metal contact, and the hat-shaped silicide 100 is used as a gate metal contact. In a better embodiment of the present invention, the silicide 100 does not fill the notches 86 and 88, and the self-aligned silicide process includes the following steps of: forming a metal layer 94 on the substrate 70, the metal layer 94 being formed of the metal Ni/Co/Pt/Pd/Mo or an alloy comprising any of the metal Ni/Co/Pt/Pd/Mo, and the metal layer 94 contacting the exposed surfaces of the gate electrode 74 and the source/drain regions 90, 92 to react with silicon; performing a first rapid thermal treatment to react the atoms in the metal layer 94 with the contacting silicon on the source/drain regions 90, 92 so as to produce the silicide 96 and the silicide 98, and react the atoms in the metal layer 94 with the contacting silicon on the gate electrode 74 and on the spacers 80, 82 so as to produce the silicide 100; performing a wet etching process to remove the unreacted portions of the metal layer 94; and performing a second rapid thermal treatment to reduce resistance of the suicides 96, 98, 100 and complete the formation of the silicides.

During the formation process of the silicide 100, the silicon atoms in the polysilicon gate electrode 74 may diffuse to the surfaces of the spacers 80 and 82. The metal layer 94 may react with the silicon atoms on the spacers 80 and 82 to form the brim of the hat-shaped silicide 100, so as to help to increase the gate metal contact area and reduce the resistance of the gate electrode. In addition, the present invention forms the notches 86 and 88 more deeply, so that the metal deposited at the bottom of the notches 86 and 88 may not be removed easily. As a result, it is also helpful to form the brim of the hat-shaped silicide 100.

In contrast to the prior art method of forming the silicide, the present invention limits the aspect ratio of the notch between the gate electrode and the spacer to be greater than 1, so that the area of the exposed sidewall surfaces increases as the depth of the notch increases. Therefore, the present invention provides an advantage of increasing the contact area between the silicide and the gate electrode. In addition, when the depth of the notch increases, the silicide extends from the top and the upper sidewall of the gate electrode to the surface of the dielectric layer underneath the notch, providing a hat-shaped cover on the gate electrode and the dielectric layer. As a result, the advantages of increasing the area of the gate metal contact and reducing the sheet resistance of the gate electrode can be achieved.

Those skilled in the art will readily observe that numerous modifications and alterations of the method may be made while utilizing the teachings of the invention.

1. A method of forming a silicide, comprising:
providing a substrate;
forming at least one gate electrode on the substrate;
forming a first dielectric layer and a second dielectric layer on the gate electrode, respectively;
removing portions of the second dielectric layer to form a spacer on either side of the gate electrode;
removing portions of the first dielectric layer to form a notch between the gate electrode and the spacer, an aspect ratio of the notch being greater than 1; and
performing a self-aligned silicide process to form the silicide on exposed surfaces of the gate electrode and the first dielectric layer underneath the notch.

2. The method of claim 1, wherein the silicide formed on the exposed surfaces of the gate electrode and the first dielectric layer provides a hat-shaped cover.

3. The method of claim 1, wherein the silicide does not fill the notch.

4. The method of claim 1, wherein the gate electrode comprises a polysilicon layer.

5. The method of claim 4, wherein the self-aligned silicide process comprises:
forming a metal layer on the substrate, the metal layer contacting a surface of the polysilicon layer;
performing a first rapid thermal treatment to react the metal layer with the contacting polysilicon layer to produce the silicide;
removing unreacted portions of the metal layer; and
performing a second rapid thermal treatment to reduce resistance of the silicide.

6. The method of claim 4, wherein silicon atoms diffuse from the polysilicon layer to the surface of the first dielectric layer underneath the notch during the self-aligned silicide process.

7. The method of claim 1, wherein a depth of the notch is about 10% to 50% of a height of the gate electrode.

8. The method of claim 1, wherein the first dielectric layer comprises a liner oxide layer.

9. The method of claim 1, wherein the first dielectric layer is a multi-layer dielectric layer.

10. The method of claim 1, wherein the second dielectric layer comprises a silicon nitride layer.

11. The method of claim 1, wherein the silicide comprises Ni/Co/Pt/Pd/Mo or an alloy comprising any of Ni/Co/Pt/Pd/Mo.

12. The method of claim 1, wherein a width of the notch is less than 400 Å.

13-24. (canceled)
